(19) United States
(12) Patent Application Publication
(10) Pub. No.: US 2023/0268353 A1
(43) Pub. Date: Aug. 24, 2023

(54) ELECTRONIC DEVICE

(71) Applicant: InnoLux Corporation, Miao-Li County (TW)

(72) Inventors: Ya-Li TSAI, Miao-Li County (TW); Hui-Ching YANG, Miao-Li County (TW); Yang-Jui HUANG, Miao-Li County (TW); Yu-Tsung LIU, Miao-Li County (TW); Te-Yu LEE, Miao-Li County (TW)

(21) Appl. No.: 18/153,765

(22) Filed: Jan. 12, 2023

(30) Foreign Application Priority Data
Feb. 24, 2022 (CN) 202210171512.9

(51) Int. Cl. H01L 27/12; H02J 50/05; G06F 3/044

(52) U.S. Cl. CPC H01L 27/124; H02J 50/05; G06F 3/044

(57) ABSTRACT

An electronic device is provided. The electronic device includes a substrate, a first conductive layer disposed on the substrate, a planarization layer disposed on the first conductive layer, an electric element, and a second conductive layer disposed on the planarization layer. The first conductive layer and the second conductive layer include an output line and a control line, respectively. The electric element is used to produce a first signal. The electronic device further includes a switching element, which is used to receive the first signal and output the first signal to the output line according to a second signal of the control line. The output line and the control line partially overlap.

### CROSS REFERENCE TO RELATED APPLICATIONS

This application claims priority of China Patent Application No. 202210171512.9 filed on Feb. 24, 2022, the entirety of which is incorporated by reference herein.

### BACKGROUND

### Field of the Disclosure

The present disclosure relates to an electronic device, and in particular to a design to reduce traces of capacitive coupling.

### Description of the Related Art

Electronic devices have become indispensable products in modern life. However, current electronic devices still do not meet consumers' expectations in all respects. For example, in a sensing circuit that is very sensitive to signals, sensing quality can easily degrade due to a high capacitive coupling. Therefore, developing a structural design capable of improving the quality and performance of an electronic device is one of the current research topics in the industry.

### BRIEF SUMMARY

An electronic device is provided. The electronic device includes a substrate, a first conductive layer disposed on the substrate, a planarization layer disposed on the first conductive layer, an electric element and a second conductive layer disposed on the planarization layer. The first conductive layer and the second conductive layer include an output line and a control line, respectively. The electric element is used to produce a first signal. The electronic device further includes a switching element, which is used to receive the first signal and output the first signal to the output line according to a second signal of the control line. The output line and the control line partially overlap.

Another electronic device is provided. The electronic device includes a substrate, a first conductive layer disposed on the substrate, a planarization layer disposed on the first conductive layer, a second conductive layer disposed on the planarization layer, a first electric element and a second electric element disposed on the planarization layer. The first conductive layer and the second conductive layer include a first output line and a second output line, respectively. The first electric element transmits a first signal via the first output line. The second electric element transmits a second signal via the second output line. The first output line and the second output line partially overlap.

A detailed description is given in the following embodiments with reference to the accompanying drawings.

### BRIEF DESCRIPTION OF THE DRAWINGS

FIG. 1 is a cross-sectional view of an electronic device in accordance with some embodiments of the present disclosure.

FIG. 2 is a circuit diagram of an electronic device in accordance with some embodiments of the present disclosure.

FIG. 3 is a schematic diagram of signal transmission of an electronic device with a multiplexer (MUX) in accordance with some embodiments of the present disclosure.

FIG. 4 is a circuit diagram of a multiplexer of an electronic device in accordance with some embodiments of the present disclosure.

FIG. 5 is a cross-sectional view of the electronic device corresponding to FIG. 4 in accordance with some embodiments of the present disclosure.

FIG. 6 is a circuit diagram of a multiplexer of an electronic device in accordance with some other embodiments of the present disclosure.

FIG. 7 is a cross-sectional view of the electronic device corresponding to FIG. 6 in accordance with some other embodiments of the present disclosure.

FIG. 8 is a schematic diagram of signal transmission of an electronic device without a multiplexer (MUX) in accordance with some embodiments of the present disclosure.

FIG. 9 is a schematic diagram of arrangement of data lines (output lines) corresponding to FIG. 8 in accordance with some embodiments of the present disclosure.

FIG. 10 is a cross-sectional view of the electronic device corresponding to FIG. 9 in accordance with some embodiments of the present disclosure.

### DETAILED DESCRIPTION

The electronic device of the embodiments of the present disclosure will be described in detail in the following context. It is noted that many different embodiments provided in the following description are used to implement different aspects of the embodiments. The specific elements and configurations described in the following detailed description are set forth in order to clearly describe some embodiments of the present disclosure. It will be apparent that the exemplary embodiments set forth herein are used merely for the purpose of illustration, and are not used to limit the scope of the present disclosure. In addition, the drawings of different embodiments may use like and/or corresponding numerals to denote like and/or corresponding elements in order to clearly describe the present disclosure. However, the use of like and/or corresponding numerals in the drawings of different embodiments is only for the purpose of simply and clearly describing some embodiments of the present disclosure, but does not suggest any correlation between different embodiments.

The present disclosure can be understood by referring to the following detailed description in conjunction with the accompanying drawings. It should be noted that in order to facilitate the reader's understanding and the simplicity of the figures, the multiple drawings in this disclosure only depict a part of the electronic device, and the specific elements in the figures are not drawn according to actual scale. In addition, the number and size of each element in the figure are only for illustration, and are not used to limit the scope of the disclosure. In addition, the number and the size of each element in the figures are only for illustration, and are not used to limit the scope of the disclosure.

It should be appreciated that the elements or devices in the figures of the present disclosure may be present in any form or configuration known to those with ordinary skill in the art. In addition, in the embodiments, relative expressions are used. For example, “lower”, “bottom”, “higher” or “top” are used to describe the position of one element relative to another. It should be appreciated that if a device is flipped upside down, an element that is “lower” will become an element that is “higher”. The descriptions of the exemplary embodiments are intended to be read in connection with the accompanying drawings, which are to be considered part of the entire written description. In addition, the following expression “the first element is disposed on the second element” includes the conditions where the first element and the second element are in direct contact, or one or more other elements are disposed between the first element and the second element so that they are not in direct contact.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present disclosure, the corresponding features, areas, steps, operations and/or components would be pointed to existence, but not limited to the existence of one or a plurality of the corresponding features, areas, steps, operations and/or components.

In addition, the relative expressions mentioned in the context, such as “upper”, “lower”, “bottom”, “front”, “back”, “left” or “right”, are used to describe the direction referring to figures. Therefore, the directional terms used are for illustration, and are not used to limit the scope of the disclosure. In the figures, each figures presents the general features of the methods, structures, and/or materials used in specific embodiments. However, these figures should not be construed as defining or limiting the scope or characteristics covered by these embodiments. For example, for the sake of clarity, the relative size, thickness, and position of each layer, region, and/or structure may be shrink or enlarged.

When a corresponding component (such as a film layer or a region) is referred to as “on another component”, it can be directly disposed on another component, or other components are disposed between the two. On the other hand, when a component is referred to as “directly on another component”, no component is disposed between the two. In addition, when a component is referred to as “on another member”, the two have a vertical relationship in the top view direction. Thus, the component may be on or under the other one, and the up-down relationship depend on the orientation of the device.

In addition, it should be understood that, although the terms “first”, “second”, “third” or the like may be used herein to describe various elements, components, or portions, these elements, components, or portions should not be limited by these terms. These terms are only used to distinguish one element, component, region, layer or portion from another element, component, region, layer or portion. Thus, a first element, component, region, layer or portion discussed below could be termed a second element, component, region, layer or portion without departing from the teachings of the present disclosure.

The terms “about”, “substantially”, “equal”, or “same” generally mean within 10% of a given value or range, or mean within 5%, 3%, 2%, 1%, or 0.5% of a given value or range. The given value here is an approximate value. That is, “about”, “substantially” may be still implied without a specific description of “about”, “substantially”. In addition, the phrase “in a range from a first value to a second value” indicates the range includes the first value, the second value, and other values in between.

It should be appreciated that, in the embodiments described in the following, the several features in different embodiments may be replaced, reorganized, and mixed to complete other embodiments without departing from the spirit of the present disclosure. The features of the various embodiments can be used in any combination as long as they do not depart from the spirit and scope of the present disclosure.

In the present disclosure, the thickness, length, and width can be measured by using an optical microscope, and the thickness can be measured by the cross-sectional image in the electron microscope, but it is not limited thereto. In addition, a certain error may be present in a comparison with any two values or directions. If the first value is equal to the second value, it implies that an error of about 10% between the first value and the second value may be present. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Unless defined otherwise, all terms (including technical and scientific terms) used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined in the present disclosure.

When the signal lines in the conductive layer has a larger coupling capacitance, the time for the signal to reach saturation (stable) becomes longer, so the reading time of the signal of the peak and the trough becomes longer. If a non-saturated signal is taken for the sake of speed, the signal difference between the peak and the trough is small, which will lead to a decrease in quality. Therefore, those skilled in the art will use the following embodiments to solve this problem for the purpose of how to reduce the coupling capacitance between the signal lines.

The electronic device provided by the present embodiment, a planarization layer may be provided, or the thickness of the planarization layer may be further increased to reduce the coupling capacitance between traces (between signal lines), thereby improving the sensing quality. In addition, by the design of a multiplexer, the electronic device provided by the present embodiment may further reduce the number of signal lines output to the integrated circuit, and may be also shorten the time for the signal to reach saturation. In addition, the use of the multiplexer may also reduce the mismatch in the number of output lines and input lines (to the integrated circuit).

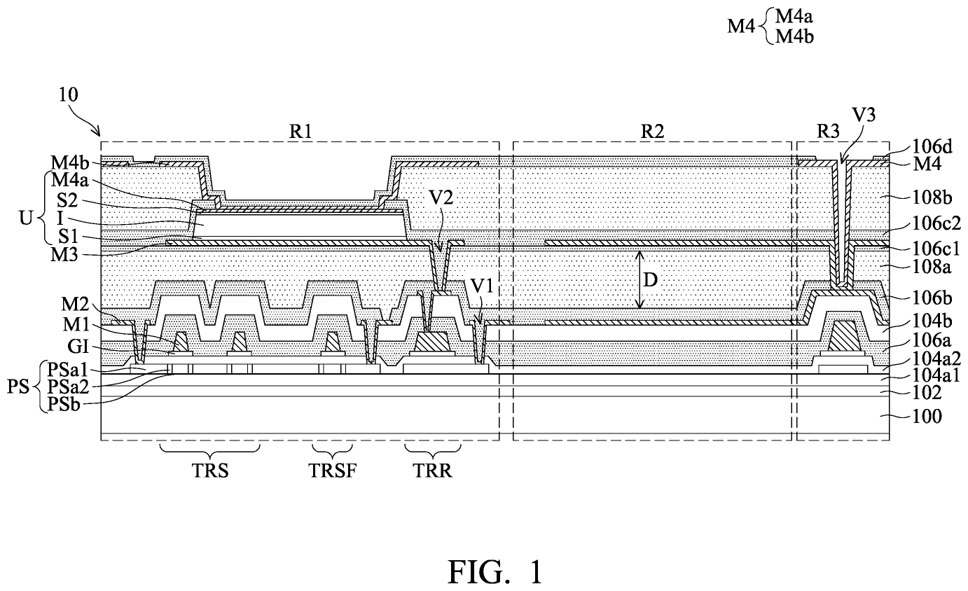

Please refer to FIG. 1, FIG. 1 shows a cross-sectional view of an electronic device in accordance with some embodiments of the present disclosure. It should be understood that, for the sake of clarity, some elements of the electronic device 10 are omitted in the figures, and only some elements are schematically shown. The structure of the electronic device 10 will be described below in conjunction with the fabrication method of the electronic device 10. It should be understood that, in some embodiments, additional operation steps may be provided before, during, and/or after the fabrication method of the electronic device 10 is performed. In some embodiments, some of the described operation steps may be replaced or omitted, and the order of some of the described operation steps may be interchangeable.

In some embodiments, the electronic device may include a display device, a backlight device, an antenna device, a sensing device, or a splicing device, but is not limited thereto. The electronic device may be a bendable electronic device or a flexible electronic device. The display device may be a non-self-luminous display device or a self-luminous display device. The antenna device may be a liquid crystal antenna device or a non-liquid crystal antenna device. The sensing device may be a sensing device for sensing capacitance, light, heat or ultrasonic waves, but not limited thereto. The electronic devices may include passive and active elements, such as capacitors, resistors, inductors, diodes, transistors, and the like. The diodes may include light-emitting diodes or photodiodes. The light-emitting diodes may include, for example, organic light-emitting diodes (OLEDs), sub-millimeter light-emitting diodes (mini LEDs), micro light-emitting diodes (micro LEDs), or quantum dot light-emitting diodes (quantum dot LEDs), but not limited thereto. The splicing device may be, for example, a display splicing device or an antenna splicing device, but not limited thereto. It should be noted that, the electronic device may be any arrangement and combination of the foregoing, but is not limited thereto. The present disclosure will be described below by taking the sensing device as an example of the electronic device, but the present disclosure is not limited thereto.

As shown in FIG. 1, the electronic device 10 may include an active region R1, a trace region R2, and a pad region R3. In some embodiments, the active region R1 may be used as a sensing region of the sensing device, and the pad region R3 may be used as a region connected to an external circuit in the display device. The trace region R2 may be disposed between the active region R1 and the pad region R3, and a multiplexer may also be further disposed in the trace region R2.

It should be noted that, in FIG. 1, the elements of the active region R1, the trace region R2, and the pad region R3 are shown on the same cross-sectional view, and other elements between the regions are omitted to simplify the drawing.

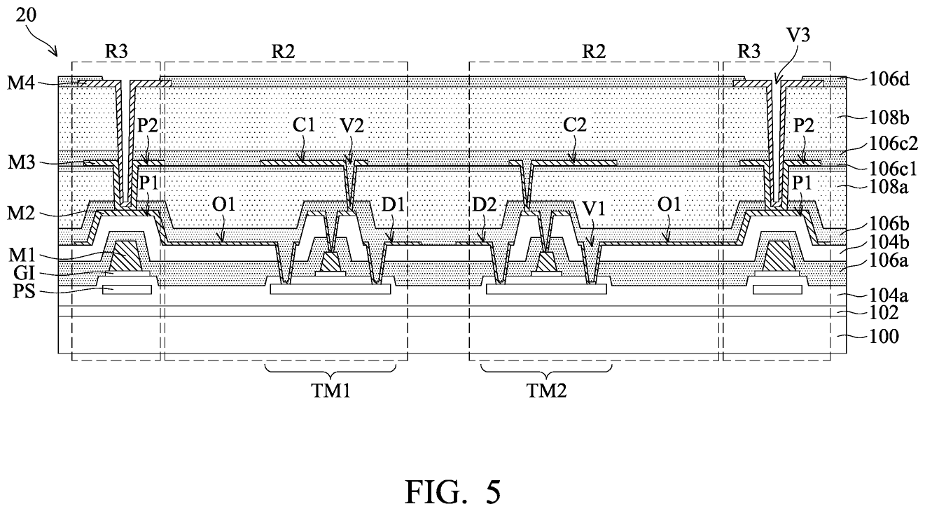

As shown in FIG. 1, the electronic device 10 may include a substrate 100, a conductive layer M1, a conductive layer M2, a planarization layer 108a, a conductive layer M3, and an electric element U. The conductive layer M1 is disposed on the substrate 100, and the conductive layer M1 may include scan lines for providing scan signals. The conductive layer M2 is disposed on the conductive layer M1, and the conductive layer M2 may include an output line (such as the output line O1 in FIG. 5), a data line (such as the data line D1 in FIG. 5) or other suitable signal lines, but is not limited thereto. The planarization layer 108a is disposed on the conductive layer M2, the conductive layer M3 is disposed on the planarization layer 108a, and the conductive layer M3 may include the control line, but is not limited thereto. Electric elements may be disposed on the planarization layer 108a, and the electric elements are used to generate the first signal.

As shown in FIG. 1, a substrate 100 is provided. In some embodiments, the substrate 100 is located in the active region R1, the trace region R2, and the pad region R3. In some embodiments, the substrate 100 may include a flexible substrate, a rigid substrate, or a combination thereof, but is not limited thereto. In some embodiments, the material of the substrate 100 may include glass, quartz, sapphire, ceramic, polyimide (PI), polycarbonate (PC), polyethylene terephthalate (PET), polypropylene (PP), other suitable materials or a combination thereof, but is not limited thereto. Furthermore, in some embodiments, the substrate 100 may include a metal-glass fiber composite sheet, or a metal-ceramic composite sheet, but is not limited thereto.

Compared with the comparative embodiment in which the electronic device (such as the sensing device) is fabricated on the wafer as the substrate, the present embodiment may reduce the manufacturing cost by using a large area of glass as the substrate.

Next, as shown in FIG. 1, a buffer layer 102 is formed on the substrate 100. In some embodiments, the buffer layer 102 is located in the active region R1, the trace region R2, and the pad region R3. In some embodiments, the buffer layer 102 may function as a barrier layer. In some embodiments, the buffer layer 102 may be a single-layer or multi-layer structure. The buffer layer 102 may include organosiloxane, silicon nitride, silicon oxide, silicon oxynitride, silicon carbide, aluminum oxide, hafnium oxide, other suitable materials, or a combination thereof, but is not limited thereto.

In some embodiments, the buffer layer 200 may be formed by a deposition process, such as chemical vapor deposition (CVD), atomic layer deposition (ALD), or spin coating or other suitable process, but is not limited thereto.

Next, as shown in FIG. 1, a dielectric layer 104a1, a semiconductor layer PS, and a dielectric layer 104a2 are formed on the buffer layer 102. In some embodiments, the semiconductor layer PS is sandwiched between the dielectric layer 104a1 and the dielectric layer 104a2. In some embodiments, the dielectric layer 104a1 and the dielectric layer 104a2 are located in the active region R1, the trace region R2, and the pad region R3, and the semiconductor layer PS is located in the active region R1 and the pad region R3.

In some embodiments, the dielectric layer 104a1 and the dielectric layer 104a2 may include a dielectric material such as silicon oxide, silicon nitride, silicon oxynitride, high-k dielectric material, or any other suitable dielectric materials, or a combination thereof, but is not limited to this.

In some embodiments, the semiconductor layer PS may include semiconductor materials such as elemental semiconductors, compound semiconductors, alloy semiconductors, other suitable materials, or combinations thereof, but is not limited thereto, such as doped or undoped polycrystalline silicon, amorphous silicon. The elemental semiconductors may include, for example, silicon, germanium. The compound semiconductor may include, for example, gallium nitride (GaN), silicon carbide, gallium arsenide, gallium phosphide, indium phosphide, indium arsenide and/or indium antimonide. The alloy semiconductor may include, for example, silicon germanium alloy (SiGe), gallium arsenide phosphorous (GaAsP), aluminum indium arsenic (AlInAs), aluminum gallium arsenic (AlGaAs), gallium indium arsenide (GaInAs), gallium indium phosphorous (GaInP) and/or gallium indium arsenide phosphorous (GaInAsP) and the like.

In some embodiments, the semiconductor layer PS includes a doped region PSa1, doped regions PSa2, and a channel region PSb between the doped regions PSa2. In some embodiments, the doped regions PSa1 and PSa2 are lightly doped regions and heavily doped regions, respectively. It should be noted that the doped region PSa1, the doped region PSa2 and the channel region PSb will be omitted in the subsequent figures to simplify the description.

In some embodiments, the dielectric layer 104a1 is formed by a deposition process similar to that described above, and the semiconductor material is formed by a deposition process such as chemical vapor deposition. Next, a specific region in the semiconductor material is doped through an implantation process, and the semiconductor material is patterned through a patterning process to form a semiconductor layer PS. Next, the dielectric layer 104a2 is formed again by a deposition process similar to that described above. In some embodiments, the patterning process includes a lithography process and an etching process, but is not limited thereto. In some embodiments, the lithography process may include photoresist coating (such as spin-on coating), soft bake, hard bake, mask alignment, exposure, post exposure bake, photoresist development, cleaning and drying, and the like, but is not limited thereto. In some embodiments, the etching process may include a dry etching process or a wet etching process, such as reactive ion etching (RIE), neutral beam etch (NBE), a suitable etching process, or the combination thereof, but is not limited thereto.

Next, as shown in FIG. 1, a gate dielectric layer GI and a conductive layer M1 are formed on the dielectric layer 104a2. In some embodiments, the gate dielectric layer GI and the conductive layer M1 are located in the active region R1 and the pad region R3. In other embodiments, the gate dielectric layer GI and the conductive layer M1 are located in the active region R1, the trace region R2 and the pad region R3 (refer to the following FIG. 5). In some embodiments, the conductive layer M1 may include scan lines, which may provide scan signals to control whether the data signals are written to the pixel units.

In some embodiments, the conductive layer M1 and the underlying semiconductor layer PS may be regarded as thin film transistors, such as the thin film transistor TRS, the thin film transistor TRSF and the thin film transistor TRR shown in the drawings. In some embodiments, the thin film transistors may include switching transistors, driving transistors, reset transistors, transistor amplifiers, or other suitable thin film transistors. Specifically, in some embodiments, in the active region R1, the thin film transistor TRR may be a reset transistor, the thin film transistor TRSF may be a transistor amplifier or a source follower, and the thin film transistor TRS may be a switching transistor, but is not limited thereto. In some embodiments, the gate dielectric layer GI, the conductive layer M1 and the underlying semiconductor layer PS are also disposed in the pad region R3, but they are not connected to the circuit, so they may not be regarded as thin film transistors.

It should be understood that the number of thin film transistors is not limited to those shown in the figures, and the electronic device 10 may have other suitable numbers or types of thin film transistors according to different embodiments. Furthermore, the types of thin film transistors may include top gate thin film transistors, bottom gate thin film transistors, dual gate or double gate thin film transistors, or combinations thereof. According to some embodiments, the thin film transistor may be further electrically connected to the capacitance element, but is not limited thereto. It should be noted that the thin film transistor may exist in various forms known to those skilled in the art, and the detailed structure of the thin film transistor will not be repeated here.

In some embodiments, the conductive layer M1 may include conductive materials, such as metal materials, transparent conductive materials, other suitable conductive materials, or a combination thereof, but is not limited thereto. The metal materials may include, for example, copper (Cu), silver (Ag), gold (Au), tin (Sn), aluminum (Al), molybdenum (Mo), tungsten (W), chromium (Cr), nickel (Ni), platinum (Pt), titanium (Ti), alloys of the foregoing metals, other suitable materials, or combinations thereof, but are not limited thereto. The transparent conductive materials may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), other suitable transparent conductive materials, or a combination thereof, but are not limited thereto. In some embodiments, the gate dielectric layer GI may include materials similar to the one described above-mentioned dielectric layer 104a, and details are not described herein again.

In some embodiments, the gate dielectric layer GI may be formed by a patterning process similar to that described above after forming the gate dielectric material by a deposition process similar to that described above. Then, the conductive material is formed by chemical vapor deposition process, physical vapor deposition process, sputtering process, electroplating process, electroless plating process, electron beam evaporation method, other suitable process, or a combination thereof, and the conductor layer M1 is formed by patterning the conductive material through a patterning process similar to the one described above.

Next, as shown in FIG. 1, a passivation layer 106a and a dielectric layer 104b are formed on the dielectric layer 104a2. In some embodiments, the passivation layer 106a covers the conductive layer M1 and the gate dielectric layer GI. In some embodiments, the passivation layer 106a and the dielectric layer 104b are located in the active region R1, the trace region R2, and the pad region R3.

In some embodiments, the material of the passivation layer 106a includes inorganic materials, organic materials, or a combination thereof, but is not limited thereto. For example, the inorganic material may include, but is not limited to, silicon nitride, silicon oxide, silicon oxynitride, other suitable materials, or a combination thereof. For example, the organic material may include polyethylene terephthalate (PET), polyethylene (PE), polyethersulfone (PES), polycarbonate (PC), polymethylmethacrylate (PMMA), polyimide (PI), other suitable materials, or a combination thereof, but is not limited thereto. In some embodiments, the material of the dielectric layer 104b is similar to the aforementioned dielectric layer 104a, and details are not described herein again.

In some embodiments, the passivation layer 106a and the dielectric layer 104b may be formed by a deposition process similar to that described above, which will not be repeated here.

Next, as shown in FIG. 1, a through hole V1 is formed through the passivation layer 106a and the dielectric layer 104b, and a conductive layer M2 is formed on the through hole V1 and the dielectric layer 104b. In some embodiments, the conductive layer M2 may be discontinuously located in the active region R1, the trace region R2, and the pad region R3. In some embodiments, the through hole V1 is located in the active region R1. In other embodiments, the through hole V1 is located in the active region R1 and the trace region R2 (refer to the following FIG. 5).

In some embodiments, the conductive layer M2 located in the active region R1 is disposed on the through hole V1, and the conductive layer M2 may be electrically connected to the thin film transistor. In some embodiments, the conductive layer M2 located in the trace region R2 is used as a signal line, for example. It may include a current signal line, a voltage signal line, a high-frequency signal line, and a low-frequency signal line, and the signal line can transmit the device operating voltage (VDD), the ground terminal voltage (VSS), or the driving element terminal voltage, but is not limited in the present disclosure. In some embodiments, the conductive layer M2 located in the pad region R3 serves as a pad to provide electrical connection to an external circuit.

In some embodiments, the through via V1 may be formed by a patterning process or an etching process similar to the mentioned above, and a conductive material may be formed on the through via V1 and the dielectric layer 104b by a deposition process similar to the one described above. Afterwards, the conductive layer M2 is formed by patterning the conductive material through a patterning process.

Next, as shown in FIG. 1, a passivation layer 106b and a planarization layer 108a are formed on the conductive layer M2. In some embodiments, the passivation layer 106b and the planarization layer 108a are located in the active region R1, the trace region R2, and the pad region R3.

In some embodiments, the material of the passivation layer 106b is similar to the aforementioned passivation layer 106a, and details are not repeated here. In some embodiments, the material of the planarization layer 108a may include organic materials, other suitable materials, or a combination thereof, but is not limited thereto. For example, the organic materials may include epoxy resins, silicone resins, acrylic resins (such as polymethylmethacrylate (PMMA), polyimide, perfluoroalkoxy alkane (PFA), other suitable materials or combinations thereof, but are not limited thereto. In an embodiment, using an organic material as the planarization layer 108a may have the effect of reducing costs and/or reducing process temperature.

In some embodiments, the passivation layer 106b and the planarization layer 108a may be formed by a deposition process similar to that described above, and thus it will not be repeated here.

In some embodiments, the thickness of the planarization layer 108a is about 1 μm˜5 μm, such as 2.5 μm˜3.5 μm. Here, the thickness refers to the thickness of the thickest region. For example, in the embodiment of FIG. 1, the planarization layer 108a in the trace region R2 has the maximum thickness D. When the thickness is less than 1 μm, the coupling capacitance between the conductive layers (respectively shown as M1 and M2, which will be described in detail later) above and below the planarization layer 108a is too large, resulting in an increase in capacitance value and a longer settling time. When the thickness is more than 5 μm, there is a possibility that the device is too thick.

In a specific embodiment, the relationship between the capacitance value and the settling time under different thicknesses of the planarization layer is measured, as shown in Table 1.

TABLE 1

| thicknesses of the planarization | capacitance | |
|---|---|---|
| layer (μm) | value (pF) | settling time (μs) |
| 2.9 | 1.34 | 2.8 |
| 3 | 1.3 | 1.2 |
| 4 | 0.979 | 1 |
| 5 | 0.786 | 0.7 |

As shown in the above table, as the thickness of the planarization layer increases, the capacitance value decreases, and the settling time also decreases. In this embodiment, the conductive layer M2 and the conductive layer M3 (which will be described later) are used as traces, which may greatly reduce the settling time.

It should be understood that, according to the present embodiment, the thickness of each element may be measured by using an optical microscope (OM), a scanning electron microscope (SEM), a film thickness profiler (α-step), an elliptical thickness measurement, and the width or height of each element, or the spacing or distance between elements may also be measured. In detail, in some embodiments, an optical microscope may be used to obtain an image of any cross-sectional structure including the element to be measured, and the thickness of the specific element may be measured.

Next, as shown in FIG. 1, a passivation layer 106c1, a through hole V2, a conductive layer M3, and an electric element U are formed on the planarization layer 108a. Specifically, the passivation layer 106c1 is formed on the planarization layer 108a; the through hole V2 passing through the passivation layer 106c1, the planarization layer 108a and the passivation layer 106b is formed; the conductive layer M3 is formed on the through hole V2 and the passivation layer 106c1; The electric element U is formed on the conductive layer M3. In some embodiments, the passivation layer 106c1 is located in the active region R1, the trace region R2, and the pad region R3. In some embodiments, the electric element U is located in the active region R1. In some embodiments, the through hole V2 is located in the active region R1 and the pad region R3. In other embodiments, the through hole V2 is located in the active region R1, the trace region R2 and the pad region R3 (refer to the following FIG. 5).

In some embodiments, the through hole V2 may be formed by a patterning process or an etching process similar to the one described above, and the conductive layer M3 is disposed on the through hole V2, and the conductive layer M3 may be electrically connected to the thin film transistor. The function of the conductive layer M3 is similar to that of the conductive layer M2. For example, the conductive layer M3 in the trace region R2 serves as a signal line, and the conductive layer M3 in the pad region R3 serves as a pad, and thus the description thereof will not be repeated herein.

In some embodiments, in the active region R1, a part of the conductive layer M3 may be used as a first electrode to be electrically connected to the electric element U. The electric element U may be electrically connected to the thin film transistor TRR, the thin film transistor TRSF and the thin film transistor TRS through the conductive layer M3 and the conductive layer M2. The electric element U may be a sensing element, which may receive light, convert the light into an electrical signal, and transmit the generated electrical signal to the elements in the active region R1 (such as the thin film transistor TRR, the thin film transistor TRSF, the thin film transistor TRS) for processing and analysis. In some embodiments, the electric device U may include a photodiode, other devices capable of converting optical signals and electrical signals, or a combination thereof, but is not limited thereto.

In some embodiments, the electric element U may include a doped layer S1, an intrinsic layer I, a doped layer S2, and a transparent conductive layer M4a. In some embodiments, the doped layer S1, the intrinsic layer I, the doped layer S2, and the transparent conductive layer M4a are disposed from bottom to top. In some embodiments, the transparent conductive layer M4a is electrically connected to the electric element U. In some embodiments, the transparent conductive layer M4a may be used to provide a common voltage to the electric element U.

In addition, in some embodiments, the electric element U may have a P-I-N structure, an N-I-P structure, or other suitable structures. In some embodiments, when light irradiates the electric element U, electron-hole pairs may be generated to form photocurrent, but it is not limited thereto. In some embodiments, the doped layer S1 may include a first conductivity type (n-type) dopant, and the doped layer S2 may include a second conductivity type (p-type) dopant, and they may form an N-I-P structure with the intrinsic layer I.

In some embodiments, the materials of the doped layer S1, the intrinsic layer I, and the doped layer S2 may include semiconductor materials, such as silicon or other suitable materials. In some embodiments, the doped layer S1, the intrinsic layer I, and the doped layer S2 may be formed by an epitaxial growth process, an ion implantation process, a chemical vapor deposition process, a physical vapor deposition process, other suitable processes, or a combination thereof, but the present disclosure is not limited thereto.

In some embodiments, the transparent conductive layer M4a may include transparent conductive materials, which include a transparent conductive oxide (TCO). For example, indium tin oxide (ITO), antimony zinc oxide (AZO), tin oxide (SnO), zinc oxide (ZnO), indium zinc oxide (IZO), indium gallium zinc oxide (IGZO), oxide Indium tin zinc oxide (ITZO), antimony tin oxide (ATO), other suitable transparent conductive materials, or a combination thereof, but the present disclosure is not limited thereto. In some embodiments, the transparent conductive layer M4a may be formed by a process similar to that of the conductive layer M1 or the conductive layer M2, and thus the details are not described herein again.

In some embodiments, the materials of the passivation layer 106c1, the through hole V2, and the conductive layer M3 are respectively similar to the passivation layer 106a, the through hole V1, and the conductive layer M2, and thus they are not repeated here. In some embodiments, the passivation layer 106c1 may be formed by a deposition process similar to that described above, and the through hole V2 through the passivation layer 106a, the planarization layer 108a, and the passivation layer 106b may be formed by a patterning process or an etching process similar to that described above. Next, a conductive material is formed by a deposition process similar to the one described above, and the conductive material is patterned by a patterning process similar to the one described above to form the conductive layer M2.

Next, as shown in FIG. 1, a passivation layer 106c2 and a planarization layer 108b are formed on the conductive layer M3 and the electric element U. In some embodiments, the passivation layer 106c2 and the planarization layer 108b are located in the active region R1, the trace region R2, and the pad region R3.

In some embodiments, the materials of the passivation layer 106c2 and the planarization layer 108b are similar to those of the passivation layer 106a and the planarization layer 108a, respectively, and thus the description thereof will not be repeated herein. In some embodiments, a passivation material is formed on the conductive layer M3 and the electric device U by a deposition process similar to the one described above, and the passivation material on the electric device U is removed by a patterning process similar to the one described above to form the passivation layer 106c2. In some embodiments, a planarization material is formed by a deposition process similar to the one described above, and the planarization material on the electric element U is removed by a patterning process similar to the one described above to form the planarization layer 108b.

Next, as shown in FIG. 1 , a through hole V3 passing through the planarization layer 108b, a transparent conductive layer M4b, and a passivation layer 106d are formed on the conductive layer M3 and on the electric element U. In some embodiments, the through hole V3 and the transparent conductive layer M4b (or the transparent conductive layer M4) are located in the active region R1 and the pad region R3; the passivation layer 106d is located in the active region R1, the trace region R2, and the pad region R3.

In some embodiments, the materials of the transparent conductive layer M4b and the passivation layer 106d are similar to the materials of the transparent conductive layer M4a and the passivation layer 106a, respectively, and thus the description thereof will not be repeated herein. In some embodiments, the through hole V3 may be formed by a patterning process or an etching process similar to the one described above. After the transparent conductive material is formed on the through hole V3 and on the planarization layer 108b by a deposition process similar to the one described above, the transparent conductive layer M4b is formed by patterning the conductive material through a patterning process. Next, after a passivation material is formed on the transparent conductive layer M4b through a deposition process similar to the one described above, the passivation material is patterned through a patterning process to form a passivation layer 106d. The transparent conductive layer M4a and the transparent conductive layer M4b may be collectively referred to as the transparent conductive layer M4.

In some embodiments, additional components such as a light shielding layer, a lens, a color filter, a pinhole and the like may still be disposed above the passivation layer 106d as required to complete the fabrication of the electronic device.

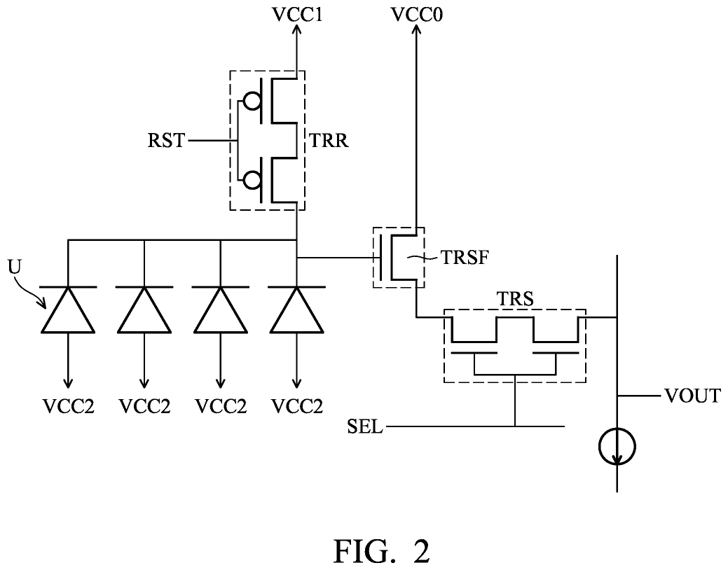

Next, please refer to FIG. 2. FIG. 2 shows a circuit diagram of an electronic device in accordance with some embodiments of the present disclosure. As shown in FIG. 2, electric elements U are electrically connected in parallel. In some embodiments, the electric elements U generate and transmit signals according to the collected light. Specifically, the signals of the electric elements U are integrated into one signal before being transmitted. With this configuration, the equivalent capacitance of the electric element U may be reduced, and the sensitivity and performance of the device may be improved. In addition, in some embodiments, the electronic device includes the scan line signal SEL and the control signal RST, which may define pixels.

Furthermore, the thin film transistor TRR is electrically connected to the thin film transistor TRSF, and the thin film transistor TRSF may be further electrically connected to the thin film transistor TRS. In some embodiments, the thin film transistor TRR may reset the electric element U (such as a photodiode), or give a specific potential; the thin film transistor TRSF may transmit the signal from the gate end to the output end; the thin film transistor TRS may serve as a switch of the control signal. In some embodiments, when the electric element U is illuminated to generate a current (the thin film transistor TRR is in an off state at this time), the gate potential may be changed, and the signal generated by the current by the thin film transistor TRSF and the thin film transistor TRS is transmitted to the output signal line VOUT. Furthermore, the electric elements U are coupled to the system voltage line VCC2.

Specifically, the thin film transistor TRR may have a first end, a second end and a control end. The first end of the thin film transistor TRR is coupled to the system voltage line VCC1, the second end of the thin film transistor TRR is coupled to electric element U, and the control end of the thin film transistor TRR is coupled to the control signal RST. The thin film transistor TRR electrically connects or disconnects the system voltage line VCC1 according to the control signal RST. When the thin film transistor TRR is electrically connected to the system voltage line VCC1, the potential of the electric element U may be reset. On the contrary, when the thin film transistor TRR is disconnected from the system voltage line VCC1, the potential of the electric element U is not reset. The system voltage line VCC1 may give a potential point for the thin film transistor TRR.

Furthermore, the thin film transistor TRSF may have a first end, a second end and a control end. The first end of the thin film transistor TRSF is coupled to the system voltage line VCC0, the second end of the thin film transistor TRSF is coupled to the first end of the thin film transistor TRS, and the control end of the thin film transistor TRSF is coupled to the second end of the thin film transistor TRR (or the electric element U). The thin film transistor TRSF may transmit the signal of the electric element U to the output signal line VOUT through the thin film transistor TRS. The system voltage line VCC0 may give a potential point of a specific bias voltage for the thin film transistor TRSF.

Furthermore, the thin film transistor TRS also has a first end, a second end and a control end. The first end of the thin film transistor TRS is coupled to the second end of the thin film transistor TRSF, and the second end of the thin film transistor TRS is coupled to the readout signal line VOUT, and the control end of the thin film transistor TRS is coupled to the scan line signal SEL. The thin film transistor TRS may electrically connect or disconnect the first end of the thin film transistor TRS and the readout signal line VOUT according to the scan line signal SEL. When the first end of the thin film transistor TRS is electrically connected to the readout signal line VOUT, the current may be output to the readout signal line VOUT. On the contrary, when the first end of the thin film transistor TRS is disconnected from the readout signal line VOUT, then no current is output to the readout signal line VOUT. In addition, for convenience, the readout signal line VOUT connected to the active region R1 is represented by a data line in the trace region R2.

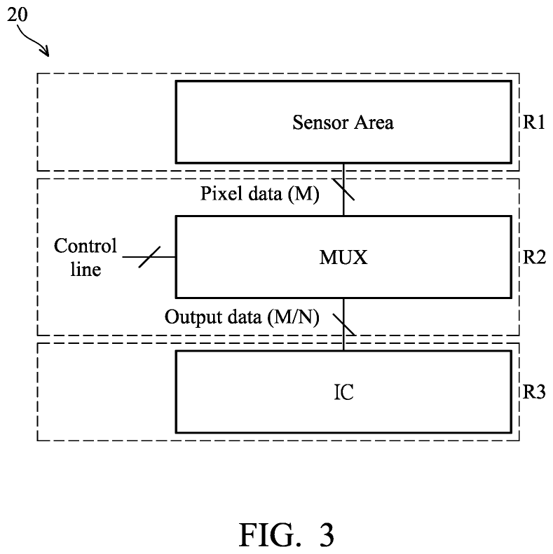

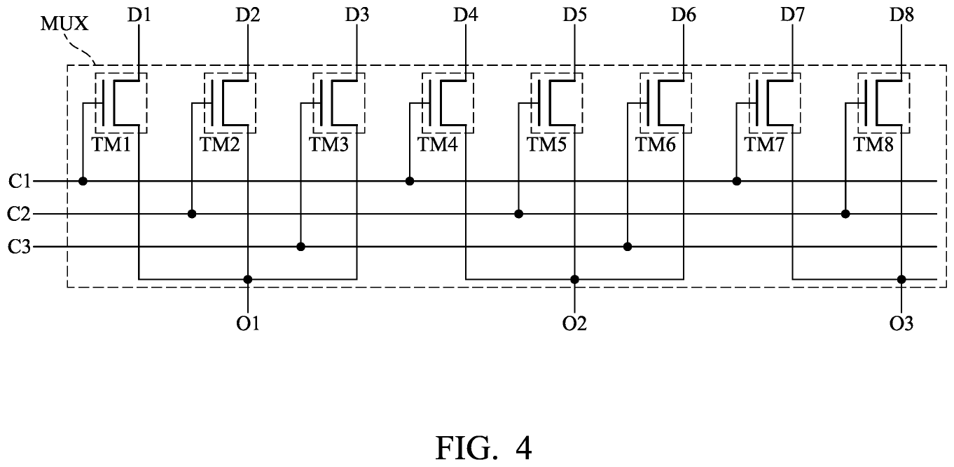

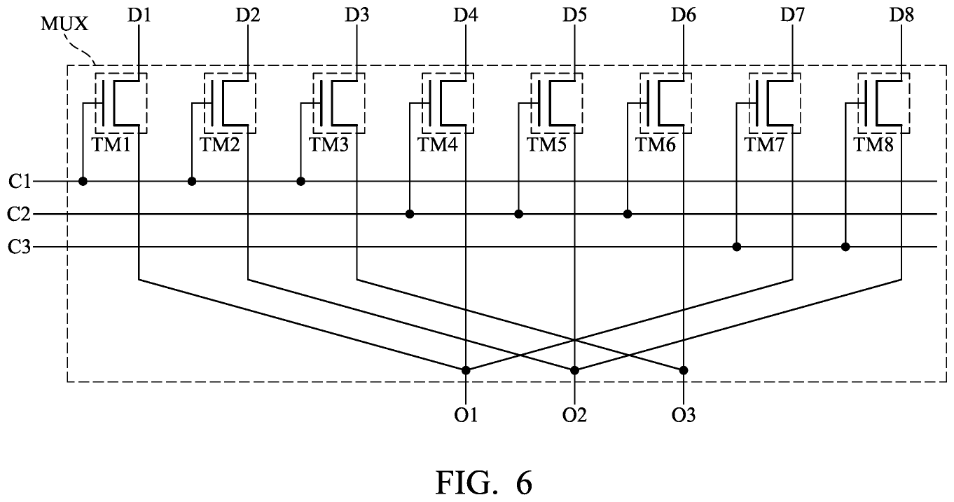

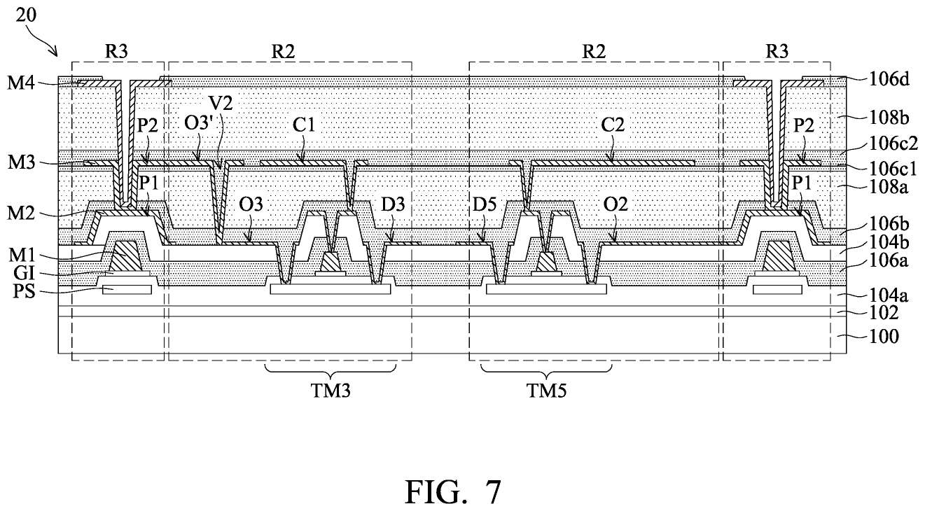

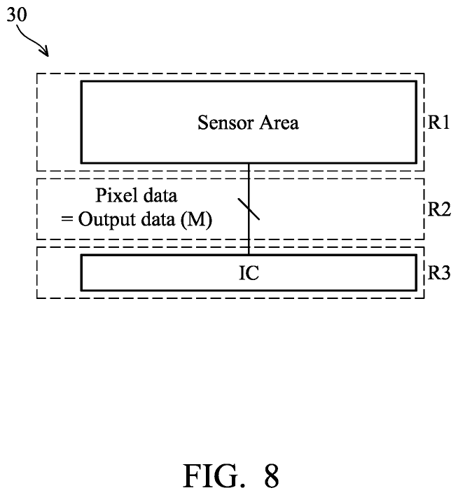

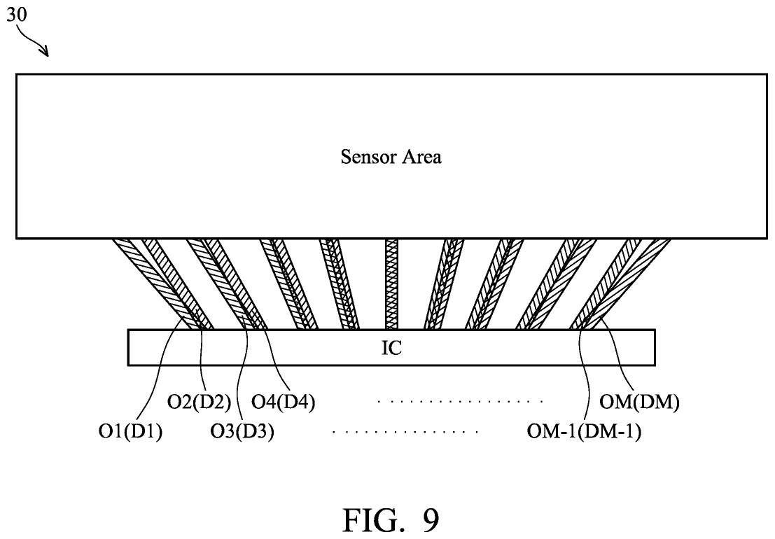

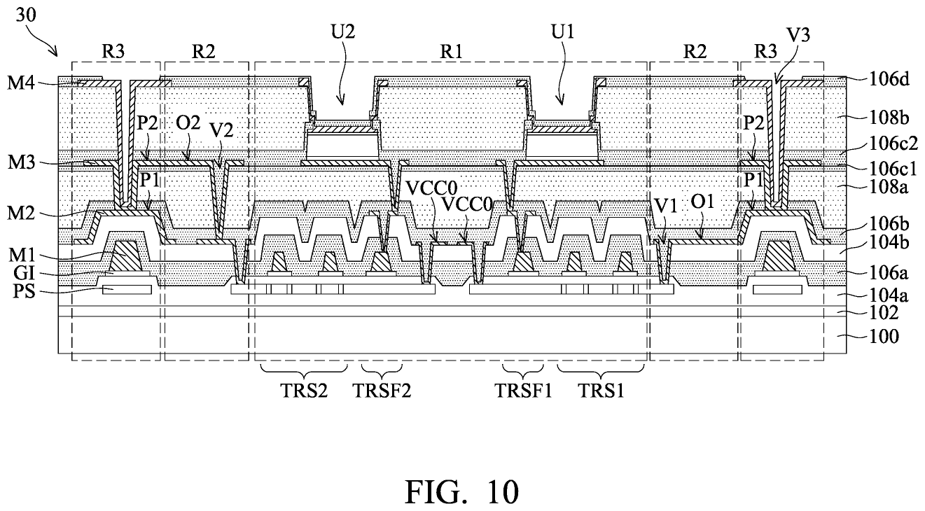

Next, the transmission of the signal lines is illustrated by the schematic diagrams of the signal transmission of the electronic device using the multiplexer (FIG. 3) and the electronic device without the multiplexer (FIG. 8). Specifically, the electronic device using the multiplexer includes the circuit diagrams as shown in FIG. 4 and FIG. 6, which may correspond to the schematic cross-sectional views as shown in FIG. 5 and FIG. 7. An electronic device without a multiplexer includes the schematic diagram of the arrangement of the data lines (output lines) in FIG. 9, which may correspond to the schematic cross-sectional view in FIG. 10.

First, the electronic device 20 using the multiplexer will be described. As shown in FIG. 3, the sensing region located in the active area R1 transmits the sensing data to the multiplexer (MUX) located in the trace region R2. The multiplexer is controlled by additional control lines to transmit the output data to the integrated circuit (IC) located in the pad region R3. It should be understood that other driving circuits may be further disposed around the sensing region, for example, on both sides of the sensing region.

Next, a circuit diagram in a multiplexer in some embodiments is illustrated. As shown in FIG. 4, the multiplexer may include switching elements, such as the thin film transistor TM1, the thin film transistor TM2 . . . , and the thin film transistor TM8. The data line D1, the data line D2, . . . the data line D8 output pixel data to the integrated circuit (external circuit) through the output line O1, the output line O2, and the output line O3. In some embodiments, each data line D1, data line D2 . . . , and data line D8 is electrically connected to switching elements (such as the thin film transistor TM1, the thin film transistor TM2 . . . , and the thin film transistor TM8), which determine whether to transmit sensing data to the output line through the control line C1, the control line C2, and the control line C3.

For example, the thin film transistor TM1 may have a first end, a second end and a control end. The first end of the thin film transistor TM1 is coupled to the data line D1, the second end of the thin film transistor TM1 is coupled to the output line O1, and the control end of the thin film transistor TM1 is coupled to the control line C1. The thin film transistor TM1 determines whether the data line D1 is electrically connected to or disconnected from the output line O1 according to the control line C1. Similarly, the thin film transistor TM2 and the thin film transistor TM3 determine whether the data line D2 and the data line D3 are electrically connected to or disconnected from the output line O1 according to the control line C2 and the control line C3, respectively. By analogy, the thin film transistor TM4, the thin film transistor TM5, and the thin film transistor TM6 determine whether the data line D4, the data line D5, and the data line D6 are electrically connected to or disconnected from the output line O2 according to the control line C1, the control line C2, and the control line C3, respectively . . . etc.

In some embodiments, the same output line may be regarded as a set of sub-multiplexers, and the data of different data lines are controlled by different control lines to output. For example, the data line D1, the data line D2 and the data line D3 are a set of sub-multiplexers, all of which output data to the output line O1.

In the present embodiment, the number of output lines may be reduced by using a multiplexer with thin film transistors and control lines.

Next, a cross-sectional view of the electronic device corresponding to FIG. 4 is shown in FIG. 5. It should be noted that, in order to clearly show the relationship between the traces, FIG. 5 shows that the thin film transistor TM1 and the thin film transistor TM2 are in the same cross-section, and the active region R1 is omitted. In addition, it should be understood that the same or similar components or elements as those described above will be denoted by the same or similar reference numerals, and their materials, fabrication methods and functions are the same or similar to those described above, so they will not be described hereinafter.

As shown on the left side of FIG. 5, in the trace region R2, the thin film transistor TM1 is electrically connected to the conductive layer M2 including the output line O1 at one end, and is electrically connected to the conductive layer M2 including the data line D1 at the other end. The thin film transistor TM1 is electrically connected to the conductive layer M3 including the control line C1 above (at the control end). It can be seen that as the control line C1 and the output line O1 are projected onto the plane of the substrate, they are at least partially overlapped. Therefore, in this embodiment, by having a certain thickness (for example, 1 μm˜5 μm) of the planarization layer, the problem that the coupling capacitance is too large due to too close between the control line and the output line may be reduced. Alternatively, the capacitance generated by the signal coupling between the control line and the output line may be reduced.

In the pad region R3, the conductive layer M2 includes a pad P1, the conductive layer M3 includes a pad P2, the pad P1 is electrically connected to the pad P2 through the through hole V2, and the output line O1 is electrically connected to the pad P1 (both the output line O1 and the first pad P1 belong to the conductive layer M2).

After the first signal is generated by the electric element (refer to FIG. 1), the first signal is transmitted to the switching element (the thin film transistor TM1) through the data line D1. Also, according to the second signal from the control line C1, the received first signal is output to the output line O1, and then connected to the external circuit through the pad P1.

Similarly, as shown on the right side of FIG. 5, in the trace region R2, the thin film transistor TM2 is electrically connected to the conductive layer M2 including the output line O1 at one end, and is electrically connected to the conductive layer M2 including the data line D2 at the other end. The thin film transistor TM2 is electrically connected to the conductive layer M3 including the control line C2 above (at the control end). It can be seen that when the control line C2 and the output line O1 are projected onto the plane of the substrate, they are at least partially overlapped. After the first signal is generated by the electric element, the first signal is transmitted to the switching element (the thin film transistor TM2) through the data line D2. Also, according to the second signal from the control line C2, the received first signal is output to the output line O2, and then connected to the external circuit through the pad P1. The remaining are similar to those described on the left side of FIG. 5 and will not be repeated here.

Next, a circuit diagram with multiplexer in other embodiments is illustrated, as shown in FIG. 6. The difference between FIG. 6 and FIG. 3 is that the sub-multiplexers are configured in different ways. For example, in FIG. 6, the thin film transistor TM1, the thin film transistor TM4, and the thin film transistor TM7 determine whether the data line D1, the data line D4 and the data line D7 are electrically connected to or disconnected from the output line O1 according to the control line C1, the control line C2 and the control line C3. The thin film transistor TM2, the thin film transistor TM5, and the thin film transistor TM8 determine whether the data line D2, the data line D5 and the data line D8 are electrically connected to or disconnected from the output line O2 according to the control line C1, the control line C2 and the control line C3 . . . etc.

Therefore, the data line D1, the data line D4 and the data line D7 are a set of sub-multiplexers, which all output data to the output line O1. By analogy, the data line D2, the data line D5 and the data line D8 are a set of sub-multiplexers, all of which output data to the output lines O2 . . . and so on.

Next, a cross-sectional view of the electronic device corresponding to FIG. 6 is shown in FIG. 7. It should be noted that, in order to clearly show the relationship between the traces, FIG. 7 shows that the thin film transistor TM3 and the thin film transistor TM5 are in the same cross-section, and the active region R1 is omitted.

As shown on the left side of FIG. 7, in the trace region R2, the thin film transistor TM3 is electrically connected to the conductive layer M2 including the output line O3 at one end, and is electrically connected to the conductive layer M2 including the data line D3 at the other end. The thin film transistor TM3 is electrically connected to the conductive layer M3 including the control line C1 above (at the control end). The conductive layer M3 further includes another output line O3′, which is electrically connected to the output line O3 through the through hole V2.

In the pad region R3, the conductive layer M2 includes a pad P1, the conductive layer M3 includes a pad P2, and the pad P1 is electrically connected to the pad P2 through the through hole V2. The output line O3 is electrically connected to another output line O3′ through the through hole V2, and the other line O3′ is electrically connected to the pad P2.

After the first signal is generated by the electric element (refer to FIG. 1), the first signal is transmitted to the switching element (the thin film transistor TM3) through the data line D3. Also, according to the second signal from the control line C1, the received first signal is output to the output line O3, and output to the pad P2 through another output line O3′, and then connected to an external circuit.

Similarly, as shown on the right side of FIG. 7, in the trace region R2, the thin film transistor TM5 is electrically connected to the conductive layer M2 including the output line O2 at one end, and is electrically connected to the conductive layer M2 including the data line D5 at the other end. The thin film transistor TM5 is electrically connected to the conductive layer M3 including the control line C2 above (at the control end). After the first signal is generated by the electric element, the first signal is transmitted to the switching element (the thin film transistor TM5) through the data line D5. Also, according to the second signal from the control line C2, the received first signal is output to the output line O2, and then connected to the external circuit through the pad P1. The remaining is similar to those described on the left side of FIG. 7 and will not be repeated here.

Next, the electronic device 30 without a multiplexer is described below. As shown in FIG. 8, the sensing area located in the active region R1 transmits pixel data to the integrated circuit (IC) located in the pad region R3 through the trace region R2. Specifically, please refer to FIG. 9. FIG. 9 is a schematic diagram illustrating the data lines in the trace region R2. If the multiplexer (MUX) is not used, all data lines (the data line D1, the data line D2 . . . the data line DM-1, the data line DM, where M is a positive integer) are directly used as output lines (the output line O1, the output line O2 . . . the output line OM-1, the output line OM, where M is a positive integer), which directly transmit data to the integrated circuit. That is, referring to the circuit diagram in FIG. 2, each readout signal line VOUT in the active region R1 is connected to the output line O1, the output line O2 . . . the output line OM-1, the output line OM in the trace region R2, respectively, so that the data is transmitted to the integrated circuit in the pad region R3. In FIG. 9, the output line O1 and the output line O2 partially overlap. By analogy, the output line O3 and the output line O4 partially overlap . . . the output line OM-1 and the output line OM partially overlap.

Next, a schematic cross-sectional view of the electronic device corresponding to FIG. 9 is shown in FIG. 10. It should be noted that FIG. 10 shows two electric elements in the active region R1 (hereinafter referred to as electric element U1 and electric element U2) and the traces connected to the two electric elements U1 and U2. However, one skilled in the art may modify the number of electric elements according to actual needs.

As shown in FIG. 10, in the active region R1, there are electric element U1 and electric element U2. In this cross-sectional view, the electric element U1 corresponds to the thin film transistors TRSF1 and the thin film transistors TRS1, and the electric element U2 corresponds to the thin film transistor TRSF2 and the thin film transistor TRS2.

Also referring to FIG. 2, the thin film transistor TRSF1 is electrically connected to the conductive layer M2 including the system voltage line VCC0 at one end, and is electrically connected to the conductive layer M2 including the output line O1 at the other end. The thin film transistor TRSF1 is electrically connected to the electric element U1 (which includes a portion of the conductive layer M3 as an electrode) above (at the control end).

On the other hand, the thin film transistor TRSF2 is electrically connected to the conductive layer M2 including the system voltage line VCC0 at one end, and is electrically connected to the conductive layer M3 including the output line O2 at the other end. The thin film transistor TRSF2 is electrically connected electric element U2 (which includes a portion of the conductive layer M3 as an electrode) above (at the control end).

In the trace region R2, the conductive layer M2 electrically connected to the thin film transistor TRS1 includes the output line O1. On the other hand, the conductive layer M3 electrically connected to the thin film transistor TRS2 through the through hole V2 includes the output line O2.

In the pad region R3, the conductive layer M2 includes a pad P1, the conductive layer M3 includes a pad P2, and the pad P1 is electrically connected to the pad P2. The output line O1 is electrically connected to the pad P1 (both the output line O1 and the pad P1 belong to the conductive layer M2). On the other hand, the output line O2 is electrically connected to the pad P2 (the output line O1 and the pad P2 both belong to the conductive layer M3)

After the first signal is generated by the electric element U1 in the active region R1, the first signal is transmitted to the pad P1 through the output line O1 (included in the conductive layer M2) through the switching element (the thin film transistor TRSF1), and then connect the external circuit. After the second signal is generated by the electric element U2 in the active region R1, the second signal is transmitted to the pad P2 through the output line O2 (included in the conductive layer M3) through the switching element (the thin film transistor TRSF2), and then connect to the external circuit.

Since the output line O1 included in the conductive layer M2 and the output line O2 included in the conductive layer M3 partially overlap (shown in FIG. 9 but not shown in FIG. 10), by the present embodiment, the planarization layer between the output line O1 and the output line O2 having a certain thickness (for example, 1 μm˜5 μm) may reduce the problem that the distance between the output lines is too close and the coupling capacitance is too large. Alternatively, the capacitance generated by the signal coupling between the control line and the output line may be reduced.

To sum up, according to some embodiments of the present disclosure, by increasing the thickness of the planarization layer, the coupling capacitance between the output signal lines (the output line and the output line, or the output line and the control line) may be reduced, and the output time (settling time) may be reduced when the signal is stable. In addition, through the design of the multiplexer, the output lines to the integrated circuit may be further reduced, thereby saving the width of the boundary region. Alternatively, the time for the signal to reach saturation may be further reduced.

While the embodiments and the advantages of the present disclosure have been described above, it should be understood that those skilled in the art may make various changes, substitutions, and alterations to the present disclosure without departing from the spirit and scope of the present disclosure. It should be noted that different embodiments may be arbitrarily combined as other embodiments as long as the combination conforms to the spirit of the present disclosure. In addition, the scope of the present disclosure is not limited to the processes, machines, manufacture, composition, devices, methods and steps in the specific embodiments described in the specification. Those skilled in the art may understand existing or developing processes, machines, manufacture, compositions, devices, methods and steps from some embodiments of the present disclosure. Therefore, the scope of the present disclosure includes the aforementioned processes, machines, manufacture, composition, devices, methods, and steps. Furthermore, each of the appended claims constructs an individual embodiment, and the scope of the present disclosure also includes every combination of the appended claims and embodiments.

What is claimed is:

1. An electronic device, comprising:
a substrate;
a first conductive layer, which includes an output line, disposed on the substrate;
a planarization layer disposed on the first conductive layer;
a second conductive layer, which includes a control line, disposed on the planarization layer;
an electric element, which is used to produce a first signal, disposed on the planarization layer; and
a switching element, which is used to receive the first signal and output the first signal to the output line according to a second signal of the control line, wherein the output line and the control line partially overlap.

2. The electronic device as claimed in claim 1, wherein the planarization layer comprises an organic material.

3. The electronic device as claimed in claim 1, wherein a thickness of the planarization layer is 1 μm˜5 μm.

4. The electronic device as claimed in claim 1, wherein the switching element includes a thin film transistor, wherein the output line is electrically connected to a first end of the thin film transistor, and the control line is electrically connected to a control end of the thin film transistor.

5. The electronic device as claimed in claim 1, wherein the first conductive layer further comprises a first pad and the second conductive layer further comprises a second pad, wherein the first pad is electrically connected to the second pad and the output line is electrically connected to the first pad.

6. The electronic device as claimed in claim 1, wherein the second conductive layer further comprises another output line, and the output line is electrically connected to the another output line.

7. The electronic device as claimed in claim 6, wherein the first conductive layer further comprises a first pad and the second conductive layer further comprises a second pad, wherein the first pad is electrically connected to the second pad and the another output line is electrically connected to the second pad.

8. The electronic device as claimed in claim 1, further comprising an active region, a trace region, and a pad region, and they do not overlap each other.

9. The electronic device as claimed in claim 8, wherein the electronic device further comprises a multiplexer in the trace region.

10. The electronic device as claimed in claim 9, wherein the multiplexer comprises the switching element.

11. The electronic device as claimed in claim 8, wherein the electronic device further comprises a through hole in the trace region, wherein the first conductive line is electrically connected to the second conductive line through the through hole.

12. The electronic device as claimed in claim 8, wherein the electronic device further comprises a through hole in the active region, wherein the first conductive line is electrically connected to the electric element through the through hole.

13. The electronic device as claimed in claim 8, wherein the electronic device further comprises a semiconductor layer in the active region.

14. The electronic device as claimed in claim 1, wherein the electronic device further comprises a through hole passing through the planarization layer.

15. The electronic device as claimed in claim 1, wherein the electronic device further comprises another planarization layer disposed on the second conductive layer and a through hole passing through the another planarization layer.

16. An electronic device, comprising:
a substrate;
a first conductive layer, which includes a first output line, disposed on the substrate;
a planarization layer disposed on the first conductive layer;
a second conductive layer, which includes a second output line, disposed on the planarization layer;
a first electric element disposed on the planarization layer and transmitting a first signal via the first output line; and
a second electric element disposed on the planarization layer and transmitting a second signal via the second output line, wherein the first output line and the second output line partially overlap.

17. The electronic device as claimed in claim 16, wherein the planarization layer comprises an organic material.

18. The electronic device as claimed in claim 16, wherein the planarization layer is 1 μm˜5 μm.

19. The electronic device as claimed in claim 16, wherein the first conductive layer further comprises a first pad and the second conductive layer further comprises a second pad, wherein the first pad is electrically connected to the second pad and the first output line is electrically connected to the first pad.

20. The electronic device as claimed in claim 16, wherein the first conductive layer further comprises a first pad and the second conductive layer further comprises a second pad, wherein the first pad is electrically connected to the second pad and the second output line is electrically connected to the second pad.
